(19) United States
(12) Patent Application Publication
(10) Pub. No.: US 2025/0311482 A1
(43) Pub. Date: Oct. 2, 2025

(54) SEMICONDUCTOR APPARATUS, PHOTOELECTRIC CONVERSION SYSTEM, AND SEMICONDUCTOR APPARATUS MANUFACTURING METHOD

(71) Applicant: CANON KABUSHIKI KAISHA, Tokyo (JP)

(72) Inventor: SHO SUZUKI, Tokyo (JP)

(21) Appl. No.: 19/088,101

(22) Filed: Mar. 24, 2025

(30) Foreign Application Priority Data
Mar. 27, 2024 (JP) 2024-050944
Dec. 27, 2024 (JP) 2024-231796

(51) Int. Cl. H10F 77/00; H10F 71/00

(52) U.S. Cl. CPC H10F 77/933; H10F 71/129

(57) ABSTRACT

A semiconductor apparatus includes a first substrate including a first wiring structure and a first semiconductor layer, a second substrate including a second wiring structure and a second semiconductor layer, and a pad to be connected to an external terminal. A first metal pattern included in the first wiring structure and a second metal pattern included in the second wiring structure are bonded together to electrically connect the first semiconductor layer and the second semiconductor layer to each other. In a planar view from a first semiconductor layer side, the second semiconductor layer is larger than the first semiconductor layer. In the planar view, the pad is located outside of the first semiconductor layer. A first protection film including nitrogen extends to at least a part of a side surface of the first semiconductor layer and at least a part of a side surface of the first wiring structure.

### BACKGROUND

### Technical Field

The present disclosure relates to a semiconductor apparatus, a photoelectric conversion system, and a semiconductor apparatus manufacturing method.

### Description of the Related Art

A semiconductor apparatus having a configuration in which semiconductor layers that have different sizes and are provided with semiconductor elements are stacked has recently been known. Japanese Patent Application Laid-Open No. 2022-89275 discusses a chip on wafer (CoW) technique for bonding a chip including a semiconductor layer and a wiring structure to a wafer including a semiconductor layer and a wiring structure by Cu—Cu bonding using metal patterns included in each wiring structure. In Cu—Cu bonding, the metal pattern included in the wiring layer of the chip and the metal pattern included in the wiring layer of the wafer are directly bonded together. Japanese Patent Application Laid-Open No. 2022-89275 also discusses a technique for bonding a support substrate after bonding the chip to the wafer.

In the technique discussed in Japanese Patent Application Laid-Open No. 2022-89275, there is a possibility that moisture or the like can intrude into the semiconductor layer included in the chip, which may degrade the function of the semiconductor apparatus. In addition, in the technique discussed in Japanese Patent Application Laid-Open No. 2022-89275, bonding defects can occur on the substrate to be bonded.

### SUMMARY

A semiconductor apparatus in the present disclosure is directed to reducing the degradation of a function of a semiconductor layer included in a chip due to the intrusion of moisture or the like into the semiconductor layer. A manufacturing method of the semiconductor apparatus in the present disclosure is directed to reducing bonding defects on a substrate to be bonded.

A semiconductor apparatus according to an aspect of the present disclosure includes a first substrate including a first wiring structure and a first semiconductor layer, a second substrate including a second wiring structure and a second semiconductor layer, and a pad to be connected to an external terminal, in which a first metal pattern included in the first wiring structure and a second metal pattern included in the second wiring structure are bonded together to electrically connect the first semiconductor layer and the second semiconductor layer to each other, in a planar view from a first semiconductor layer side, the second semiconductor layer is larger than the first semiconductor layer, in the planar view, the pad is located outside of the first semiconductor layer, a first protection film extends to at least a part of a side surface of the first semiconductor layer and at least a part of a side surface of the first wiring structure, and the first protection film includes nitrogen.

A semiconductor apparatus according to another aspect of the present disclosure includes a first substrate including a first wiring structure and a first semiconductor layer including a photoelectric conversion element, and a second substrate including a second wiring structure and a second semiconductor layer, in which a first metal pattern included in the first wiring structure and a second metal pattern included in the second wiring structure are bonded together to electrically connect the first semiconductor layer and the second semiconductor layer to each other, in a planar view from a first semiconductor layer side, the second semiconductor layer is larger than the first semiconductor layer, a first protection film extends to at least a part of a side surface of the first semiconductor layer and at least a part of a side surface of the first wiring structure, and the first protection film includes nitrogen.

A semiconductor apparatus manufacturing method according to still another aspect of the present disclosure includes preparing a bonded body obtained by stacking a first substrate including a first wiring structure and a first semiconductor layer including a photoelectric conversion element and a second substrate including a second wiring structure and a second semiconductor layer, forming a protection film on a top surface and a side surface of the bonded body, the protection film including a first protection film including nitrogen and a second protection film, the first protection film and the second protection film being located in this order, and removing a part of the protection film to expose at least a part of the first protection film. In the preparation of the bonded body, a first metal pattern included in the first wiring structure and a second metal pattern included in the second wiring structure are bonded together to electrically connect the first semiconductor layer and the second semiconductor layer to each other, and in a planar view from a first semiconductor layer side, the second semiconductor layer is larger than the first semiconductor layer.

Further features of the present disclosure will become apparent from the following description of exemplary embodiments with reference to the attached drawings.

### BRIEF DESCRIPTION OF THE DRAWINGS

FIG. 1A is a schematic plan view illustrating a semiconductor apparatus according to a first exemplary embodiment. FIG. 1B is a schematic cross-sectional view of the semiconductor apparatus according to the first exemplary embodiment.

FIGS. 2A and 2B are schematic cross-sectional views each illustrating a bonded portion of the semiconductor apparatus according to the first exemplary embodiment.

FIGS. 3A and 3B are schematic cross-sectional views each illustrating a bonded portion of the semiconductor apparatus according to the first exemplary embodiment.

FIG. 4 is a process cross-sectional view illustrating a manufacturing method of the semiconductor apparatus according to the first exemplary embodiment.

FIG. 5 is a process cross-sectional view illustrating a manufacturing method of the semiconductor apparatus according to the first exemplary embodiment.

FIG. 6 is a process cross-sectional view illustrating a manufacturing method of the semiconductor apparatus according to the first exemplary embodiment.

FIG. 7 is a process cross-sectional view illustrating a manufacturing method of the semiconductor apparatus according to the first exemplary embodiment.

FIG. 8 is a process cross-sectional view illustrating a manufacturing method of the semiconductor apparatus according to a second exemplary embodiment.

FIG. 9 is a process cross-sectional view illustrating a manufacturing method of the semiconductor apparatus according to the second exemplary embodiment.

FIG. 10 is a process cross-sectional view illustrating a manufacturing method of the semiconductor apparatus according to the second exemplary embodiment.

FIG. 11 is a c process ross-sectional view illustrating a manufacturing method of the semiconductor apparatus according to a third exemplary embodiment.

FIG. 12 is a process cross-sectional view illustrating a manufacturing method of the semiconductor apparatus according to the third exemplary embodiment.

FIG. 13A is a schematic plan view illustrating a semiconductor apparatus according to a fourth exemplary embodiment. FIG. 13B is a schematic cross-sectional view of the semiconductor apparatus according to the fourth exemplary embodiment.

FIG. 14 is a process cross-sectional view illustrating a manufacturing method of the semiconductor apparatus according to the fourth exemplary embodiment.

FIG. 15 is a process cross-sectional view illustrating a manufacturing method of the semiconductor apparatus according to the fourth exemplary embodiment.

FIG. 16 is a process cross-sectional view illustrating a manufacturing method of the semiconductor apparatus according to the fourth exemplary embodiment.

FIG. 17 is a process cross-sectional view illustrating a manufacturing method of the semiconductor apparatus according to the fourth exemplary embodiment.

FIG. 18 is a process cross-sectional view illustrating a manufacturing method of the semiconductor apparatus according to the fourth exemplary embodiment.

FIG. 19 is a process cross-sectional view illustrating a manufacturing method of the semiconductor apparatus according to a fifth exemplary embodiment.

FIG. 20 is a process cross-sectional view illustrating a manufacturing method of the semiconductor apparatus according to the fifth exemplary embodiment.

FIG. 21 is a process cross-sectional view illustrating a manufacturing method of the semiconductor apparatus according to the fifth exemplary embodiment.

FIG. 22 is a process cross-sectional view illustrating a manufacturing method of the semiconductor apparatus according to the fifth exemplary embodiment.

FIG. 23 is a process cross-sectional view illustrating a manufacturing method of the semiconductor apparatus according to a sixth exemplary embodiment.

FIG. 24 is a process cross-sectional view illustrating a manufacturing method of the semiconductor apparatus according to the sixth exemplary embodiment.

FIG. 25 is a block diagram illustrating a configuration of a photoelectric conversion system according to a seventh exemplary embodiment.

FIGS. 26A and 26B illustrate a configuration and operation of a moving body according to an eighth exemplary embodiment.

### DESCRIPTION OF THE EMBODIMENTS

Exemplary embodiments of the present disclosure will be described in detail below with reference to the drawings. The following exemplary embodiments are not intended to limit the scope of the present disclosure. Multiple features are described in the exemplary embodiments, but limitation is not made to a disclosure that requires all such features, and multiple such features can be combined as appropriate. Further, in the attached drawings, the same reference numerals are given to the same or similar configurations, and redundant description thereof is omitted.

In the following exemplary embodiments, a photoelectric conversion apparatus will be mainly described as an example of semiconductor apparatuses according to the exemplary embodiments. However, the semiconductor apparatuses according to the exemplary embodiments can be applied not only to a photoelectric conversion apparatus, but also to a light-emitting apparatus and the like. In the following exemplary embodiments, an image capturing apparatus will be described as an example of the photoelectric conversion apparatus. However, the photoelectric conversion apparatus is not limited only to this example. For example, the semiconductor apparatuses according to the exemplary embodiments can also be applied to photoelectric conversion apparatuses, such as a ranging apparatus (e.g., an apparatus for measuring a distance using focus detection or time of flight (ToF)) and a photometric apparatus (e.g., an apparatus for measuring the amount of incident light).

In the following exemplary embodiments, connections between circuit elements may also be mentioned. In this case, even in a case where there is another element between elements of interest, the elements of interest are assumed to be connected, unless otherwise noted. For example, assume that an element A is connected to one node of a capacitive element C having a plurality of nodes, and an element B is connected to another node of the capacitive element C. Even in such a case, the elements A and B are assumed to be connected, unless otherwise noted.

A metal member such as a conductive line or a pad described herein can be made of a single metal of a certain element or a mixture (alloy). For example, a conductive line described as a copper conductive line can contain only copper or can contain copper as a main component and other components. For example, a pad to be connected to an external terminal can contain only aluminum or can contain aluminum as a main component and other components. The copper conductive line and the aluminum pad described herein are merely examples, and can be changed to various kinds of metal.

In the following description, the term “wafer” refers to a substrate obtained before dicing of the substrate on which a plurality of semiconductor elements is formed by a semiconductor process. The term “chip” refers to each semiconductor element obtained after the wafer is diced. For example, a plurality of image sensors and a plurality of circuit units can be formed on the wafer.

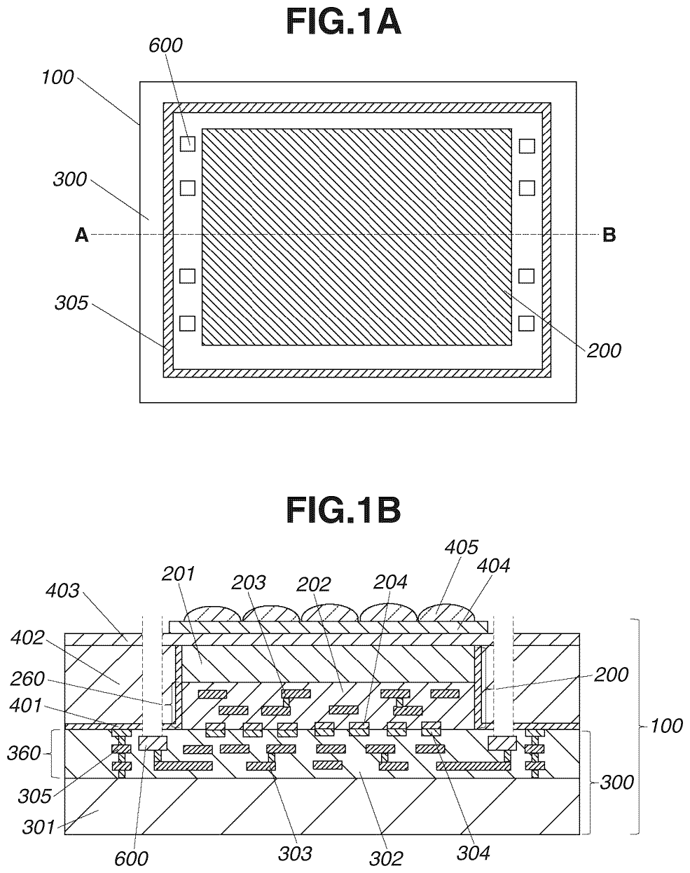

A semiconductor apparatus 100 (photoelectric conversion apparatus) and a manufacturing method of the semiconductor apparatus 100 according to a first exemplary embodiment of the present disclosure will now be described with reference to FIGS. 1A to 7.

A schematic configuration of the semiconductor apparatus 100 will be described with reference to FIGS. 1A and 1B. FIG. 1A is a schematic plan view of the semiconductor apparatus 100, and FIG. 1B is a schematic cross-sectional view of the semiconductor apparatus 100 taken along a line A-B illustrated in FIG. 1A. The term “plan” used herein refers to a plane when viewed from a side (first semiconductor layer side) of a semiconductor layer 201 in a structure in which the semiconductor layer 201 (first semiconductor layer) and a semiconductor layer 301 (second semiconductor layer), both of which will be described below, are stacked. The term “cross-section” refers to a plane when viewed from a direction perpendicular to the direction in which the semiconductor layer 201 and the semiconductor layer 301 are stacked, or a plane that passes through the semiconductor layer 201 and the semiconductor layer 301. The term “planar view” refers to a case where the above-described plane is viewed. The term “cross-sectional view” refers to a case where the cross-section that passes through the semiconductor layer 201 and the semiconductor layer 301 is viewed. For example, the term “planar view” refers to a view from a direction perpendicular to a surface on which a plurality of pixels is arranged in a two-dimensional array.

As illustrated in FIGS. 1A and 1B, the semiconductor apparatus 100 includes a substrate 200 (first substrate) including the semiconductor layer 201 and a wiring structure 260 (first wiring structure), and a substrate 300 (second substrate) including the semiconductor layer 301 and a wiring structure 360 (second wiring structure). The wiring structure 260 includes a plurality of wiring layers 203 and a wiring interlayer film 202 located between the wiring layers 203. Each wiring layer 203 includes a plurality of metal patterns, and the wiring interlayer film 202 is also located between the metal patterns. The metal pattern of a certain wiring layer may be electrically connected to the metal pattern of another wiring layer adjacent to the wiring layer via a via plug. Similarly, the wiring structure 360 includes a plurality of wiring layers 303 and a wiring interlayer film 302 located between the wiring layers 303. Each wiring layer 303 includes a plurality of metal patterns, and the wiring interlayer film 302 is also located between the metal patterns.

The semiconductor layer 201 includes a first semiconductor element, and the semiconductor layer 301 includes a second semiconductor element. An example will be described below in which the substrate 200 constitutes an image sensor and the substrate 300 constitutes a circuit unit. In the following example, the semiconductor layer 201 of the substrate 200 includes a photodiode serving as a photoelectric conversion element as the first semiconductor element. The semiconductor layer 301 of the substrate 300 includes a signal processing circuit for processing signals from the photoelectric conversion element as the second semiconductor element. The first semiconductor element is not limited only to a photoelectric conversion element, but may be any other element such as a transistor, or a light-emitting element. If the first semiconductor element is a light-emitting element, the second semiconductor element can be, for example, a circuit for controlling light emission of the light-emitting element.

In the semiconductor layer 201, a plurality of pixels each including the photoelectric conversion element, a transfer transistor, an amplification transistor, and a reset transistor is arranged. A pixel includes at least one photoelectric conversion element. A configuration example will be described below in which one pixel includes a photoelectric conversion element, a transfer transistor, an amplification transistor, and a reset transistor. The source of the transfer transistor is connected to the photoelectric conversion element, and the drain of the transfer transistor is connected to the gate electrode of the amplification transistor. A node corresponding to the gate electrode of the amplification transistor is set as a floating diffusion (FD). The reset transistor is connected to the FD, and the potential of the FD is set to any potential (e.g., reset potential). In this case, the amplification transistor is a part of a source follower circuit and outputs a signal depending on the potential of the FD to a signal line.

The layout of the amplification transistor and the reset transistor is not limited to the above-described layout. For example, the amplification transistor and the reset transistor can be located in the semiconductor layer 301. This configuration makes it possible to increase the area of the photoelectric conversion element as compared to a case where all the components of the pixels are located in the semiconductor layer 201. Consequently, the sensitivity can be improved. Even when the area of the photoelectric conversion element is not big, a larger number of photoelectric conversion elements can be provided, which leads to an increase in the number of pixels.

In the semiconductor layer 301, peripheral circuits, including a readout circuit and a control circuit, are located. The peripheral circuits include a vertical scanning circuit serving as a control circuit for supplying a control signal to the gate electrode of the transistor of each pixel. The peripheral circuits also include a readout circuit for holding signals output from each pixel and performing signal processing such as amplification, addition, and analog-to-digital (AD) conversion. The peripheral circuits also include a horizontal scanning circuit as a control circuit for controlling a timing of sequentially outputting signals from the readout circuit.

The first semiconductor element can be an avalanche photodiode. In this case, the transistors need not necessarily be provided in the semiconductor layer 201.

The semiconductor apparatus 100 is formed by bonding the substrate 200 to the substrate 300. The wiring layers located on the second substrate side of the substrate 200 in the wiring structure 260 include a metal pattern 204 (first metal pattern). The wiring layers located on the substrate 200 side of the substrate 300 in the wiring structure 360 include a metal pattern 304 (second metal pattern). The substrate 200 and the substrate 300 are electrically connected by bonding the metal patterns included in the substrate 200 and the substrate 300. For example, the metal pattern 204 and the metal pattern 304 can be made of a material composed mainly of copper (Cu) and can be electrically connected by Cu—Cu bonding.

The substrate 300 includes a guard structure 305 located outside of the substrate 200 in a planar view. Specifically, the substrate 300 includes the guard structure 305 on the outside of an edge (end) of the substrate 200 in a planar view. The guard structure 305 is provided to prevent the second semiconductor element of the substrate 300 from being adversely affected by dicing when the semiconductor apparatus 100 is diced into individual chips. The guard structure 305 is desirably connected to the semiconductor layer 301, and it is also desirable to continuously form a metal layer over the surface (surface corresponding to the bonded surface to be bonded to the substrate 200) of the substrate 300. For example, as illustrated in FIG. 1B, it is desirable that the guard structure 305 has a configuration in which metal portions, such as a plurality of contact plugs, a plurality of metal patterns, and a plurality of via plugs, are continuously formed over the area from the surface of the semiconductor layer 301 to the top surface of the substrate 300. This configuration prevents the semiconductor element from being adversely affected by dicing.

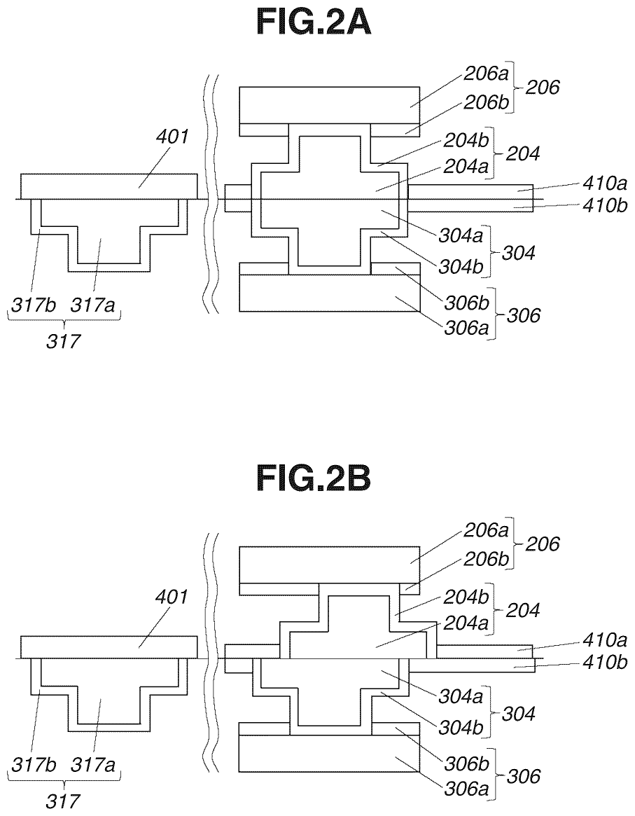

The guard structure 305 includes a metal pattern (third metal pattern) 317 (FIGS. 2A and 2B) that constitutes a part of the bonded surface of the substrate 300. The metal pattern 317 is located at a same height where the metal pattern 304 is located. The metal pattern 317 is located outside of the semiconductor layer 201 in a planar view. At least a part of the guard structure 305 can be formed on the outside of the substrate 200 in a planar view, thereby making it possible to increase the region of the substrate 300 to be effectively used.

In the first exemplary embodiment, a contact portion that is in contact with each of the metal pattern 317 and a protection film (first protection film) 401 that is in contact with the metal pattern 317 is located outside of the semiconductor layer 201 in a planar view. In other words, the contact portion is located outside of an edge (end) of the semiconductor layer 201 in a planar view. The protection film 401 is in contact with the metal pattern 317, thereby preventing the metal element of the metal pattern 317 from being diffused to the semiconductor layer 201 via a protection film (second protection film) 402.

The metal pattern 317 is electrically connected to the semiconductor layer 301. For example, the metal pattern 317 can be supplied with a fixed potential. This prevents a failure that may occur due to floating of the metal pattern 317.

The guard structure can may be formed in an enclosing ring shape, for example, in a planar view. The diffusion of the metal element included in the metal pattern 317 included in the guard structure 305 to the semiconductor layer 201 can degrade the characteristics of the substrate 200. In other words, the performance of protecting the semiconductor apparatus can deteriorate. Accordingly, in the first exemplary embodiment, the protection film 401 including nitrogen is provided in contact with the metal pattern 317 of the guard structure 305 so as to prevent the diffusion of the metal element. It is desirable to provide the protection film 401 to cover an upper portion of the guard structure 305 in a cross-sectional view.

For example, as illustrated in FIG. 1A, the guard structure 305 can be formed in an enclosing shape in a planar view. The wiring structure 260 of the substrate 200 can also be provided with a guard structure.

If the protection film 401 covers a side surface of the wiring structure 260, the protection film 401 need not necessarily be in contact with the metal pattern 317. This is because, in this case, a diffusion prevention film provided in the vicinity of the metal pattern 204 or the like makes it possible to prevent the diffusion of the metal element to the semiconductor layer 201 via the wiring structure 360.

The guard structure 305 is not necessarily made of metal. The guard structure 305 may be made of any material as long as the material can prevent adverse effects of dicing. For example, an insulating material that is different from the material of the wiring interlayer film 302 can be located between the metal patterns, instead of using a via plug made of metal.

The protection film 401 extends to at least a part of the side surface of the semiconductor layer 201 and at least a part of the side surface of the wiring structure 260. As illustrated in FIG. 1B, the protection film 401 is desirably located on the entire side surface of the semiconductor layer 201 and on the entire surface of the wiring structure 260. With this configuration, the moisture resistance can be improved.

As illustrated in FIG. 1A, a plurality of pads 600 is located on the inside of the guard structure 305. Each pad 600 outputs a signal (image signal) based on charges generated in the photoelectric conversion element to the substrate 200 and the substrate 300, and accepts a voltage or the like to drive the peripheral circuits from an external apparatus. While FIG. 1A illustrates an example where the pads 600 are located on the substrate 300, the pads 600 can also be located on the substrate 200.

On the substrate 200 of the semiconductor apparatus 100, optical structures such as a color filter 404 and microlenses 405 are located on the opposite side of a circuit substrate serving as the substrate 300.

As described above, the semiconductor apparatus according to the first exemplary embodiment is a back-illuminated stacked sensor using a chip on wafer (CoW) technique.

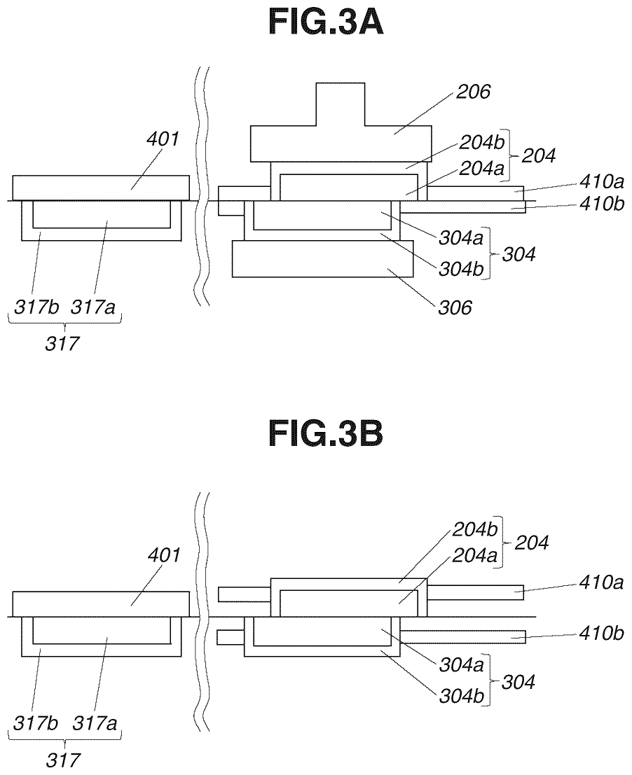

FIGS. 2A and 2B and FIGS. 3A and 3B are enlarged views illustrating the metal patterns 204, 304, and 317 on the bonded surface between the substrate 200 and the substrate 300. Any of these examples can be used for the first exemplary embodiment.

As illustrated in FIGS. 2A and 2B and FIGS. 3A and 3B, the metal patterns 204, 304, and 317 can include a conductors 204a, 304a and 317a and a conductive films 204b, 304b, and 317b, respectively. The conductive films 204b, 304b, and 317b are made of different materials from those of the conductors 204a, 304a, and 317b, respectively. The conductors 204a, 304a, and 317a can be made of different materials from each other, but are desirably made of the same material. The conductive films 204b, 304b, and 317b each function as a film for preventing the diffusion of the metal element of the conductor. The conductive films 204b, 304b, and 317b can be made of different materials, but are desirably made of the same material. The side surface of a conductor and the surface of the conductor opposite to the surface in contact with another conductor is desirably covered with a conductive film. With this configuration, the conductor is covered with the conductive film after bonding, thereby suppressing the generation of a dark current or a leak current. For example, Cu can be used as the conductor.

In a case described below, the conductors 204a, 304a, and 317a are made of the same material, and the conductive films 204b, 304b, and 317b are made of the same material. In the following description, assume that a conductive line of a single damascene structure is formed by a single damascene method in which a groove serving as a conductive line is formed in a wiring interlayer film and a conductive film functioning as a barrier metal and a conductor made of copper or the like are buried in the groove, and the conductive line is buried in the wiring interlayer film. A conductive line of a dual damascene structure has a configuration in which a conductive line and a via hole are integrally formed, and includes the conductive line and the via hole that are buried in a wiring interlayer film. The conductive line of the dual damascene structure is formed by a dual damascene method in which a conductive line and a groove serving as a via hole are formed in the wiring interlayer film and a conductive film functioning as a barrier metal and a conductor made of copper or the like are buried in the groove.

As illustrated in FIG. 2A, the conductor 204a of the metal pattern 204 is in contact with the conductor 304a of the metal pattern 304. The conductive film 204b is located in contact with a surface other than the contact surface of the conductor 204a that is in contact with the conductor 304a so that the conductive film 204b can cover the surface. The conductive film 204b is located in contact with a metal pattern 206 of the adjacent wiring layer. The metal pattern 206 includes a conductor 206a and a conductive film 206b. The conductor 206a is composed mainly of, for example, Cu, and the conductive film 206b is composed mainly of, for example, a material that prevents diffusion of Cu. The conductive film 206b can also be located on the opposite side of the metal pattern 204. The conductive film 204b penetrates through a part of the conductive film 206b and is in contact with the conductor 206a.

The conductor 317a of the metal pattern 317 is in contact with the protection film 401. This configuration makes it possible to prevent diffusion of the conductor 317a.

As illustrated in FIG. 2B, the metal pattern 204 and the metal pattern 304 can be misaligned at the bonded surface. In this case, the conductor 204a is in contact with both the conductor 304a and the conductive film 304b. The misalignment between the metal pattern 204 and the metal pattern 304 to be bonded can cause diffusion of the metal element of the conductor of each metal pattern to the wiring interlayer film. Thus, diffusion prevention films 410a and 410b are provided so as to prevent the diffusion of metal of the metal pattern 204 and the metal pattern 304. As described below, the diffusion prevention films 410a and 410b are provided before the substrate 200 and the substrate 300 are bonded together, thereby preventing the diffusion of metal elements of the metal patterns 204 and 304. In contrast, the chip-shaped substrate 200 is bonded to the wafer-shaped substrate 300, it is thus difficult to leave only the diffusion prevention film in the metal pattern 317. The diffusion prevention film 410a and the protection film 401 can be provided in different processes, accordingly.

The diffusion prevention film 410a and the protection film 401 can be made of different materials or the same material. For example, the diffusion prevention film 410a can be made of silicon nitride or the like. As illustrated in FIGS. 2A, 2B, and the like, the protection film 401 desirably has a thickness greater than the thickness of the diffusion prevention film 410a. The protection film 401 and the diffusion prevention film 410a can have the same thickness.

The thickness of the protection film 401 is preferably, for example, in a range from 50 nm (nanometers) to 500 nm, and more preferably, in a range from 100 nm to 300 nm. The thickness of the protection film 401 is preferably, for example, ¼ to ½ times of the thickness of the metal pattern 317. A configuration illustrated in FIG. 3A differs from the configuration illustrated in FIG. 2B in regard to the shape of each of the metal patterns 204, 304, and 317. The metal pattern 206 can be formed of a conductor and a conductive film.

Between the protection film 401 and the semiconductor layer 201, an insulating film can be interposed. The thickness of the insulating film interposed between the protection film 401 and the semiconductor layer 201 is preferably, for example, 300 nm or less in terms of the protection function. In other words, a shortest distance between the side surface of the semiconductor layer 201 and the protection film 401 is preferably 300 nm or less. The insulating film can include, for example, silicon oxide (SiO). This configuration makes it possible to reduce the stress between the protection film 401 including silicon nitride (SiN) and the semiconductor layer 201 including silicon (Si).

As illustrated in FIG. 3B, the diffusion prevention films 410a and 410b can be provided at a location apart from the bonded surface. Even in this case, the diffusion prevention films 410a and 410b make it possible to prevent the diffusion of the metal elements from the metal patterns 204 and 304 to the adjacent wiring layers.

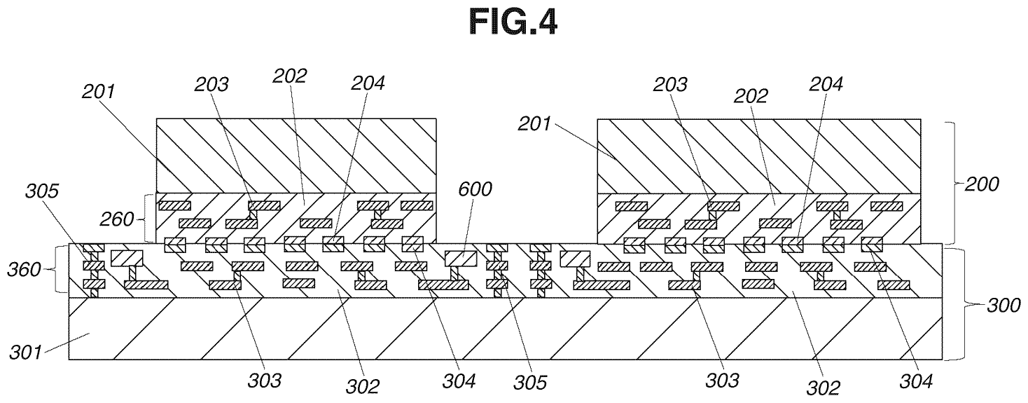

Next, a manufacturing method of the semiconductor apparatus according to the first exemplary embodiment will be described with reference to FIGS. 4 to 7. FIGS. 4 to 7 are process cross-sectional views each illustrating the manufacturing method of the semiconductor apparatus according to the first exemplary embodiment.

As illustrated in FIG. 4, a bonded body is prepared which is obtained by stacking and bonding the substrate 200 including a chip-shaped image sensor onto the substrate 300 in the wafer state including a plurality of circuit units. The substrate 300 is provided with the metal pattern 304, which is composed mainly of, for example, Cu, and the substrate 200 is provided with the metal pattern 204. The substrate 300 and the substrate 200 can be bonded together by Cu—Cu metal bonding and covalent bonding between the wiring interlayer film 202 and the wiring interlayer film 302. In this case, formation of a diffusion prevention film including, for example, SiN in a part of the wiring interlayer film 202 and the wiring interlayer film 302 makes it possible to prevent the diffusion of the metal element included in the metal pattern 304 of the wiring layer and the metal element included in the metal pattern 204 of the wiring layer. In this case, the guard structure 305 is in a state where the wiring layer in the same layer as the wiring layer in which the metal pattern 304 is located is exposed. A metal layer serving as each pad 600 is formed in the wiring structure 360. In the first exemplary embodiment, the pads 600 are formed in the wiring structure 360, but instead can be formed in the wiring structure 260 in the chip-shaped substrate 200. In the case of forming the pads 600 outside of the substrate 200 in a planar view, openings can be formed to expose the pads 600 without penetrating through the semiconductor layer 201.

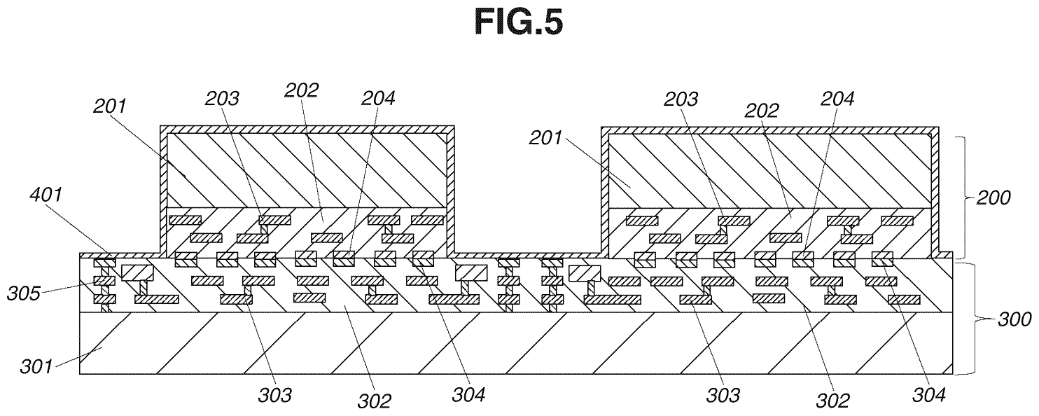

Next, for example, a silicon nitride film is deposited to form the protection film 401 including nitrogen with a photolithography technique and an etching technique, as illustrated in FIG. 5. The protection film 401 is formed on the top surface and the side surface of the bonded body. The first protection film preferably includes SiN or silicon oxynitride (SiON). With this configuration, the reliability of the semiconductor apparatus can easily be ensured.

In the case of forming the protection film 401, a film similar to the protection film can be left on the side surface of the substrate 200. In this case, the moisture resistance of the substrate 200 and the like can be improved. The protection film 401 is also removed from the surface on which the semiconductor apparatus 100 is to be diced, thereby avoiding a failure such as peeling of the film during dicing.

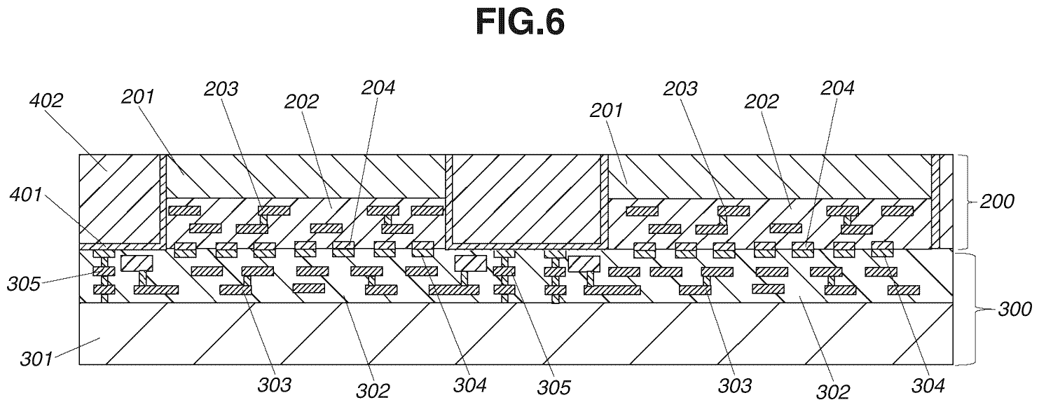

Next, for example, silicon oxide is deposited and planarization is performed to thereby form the protection film 402, as illustrated in FIG. 6. The thickness of the substrate 200 is, for example, 10 μm to 30 μm. The film thickness of the protection film 402 to be deposited is desirably greater than the height of the substrate 200. For example, it is preferable to form the protection film 402 with a ten times or more thickness of the protection film 401. The protection film 402 preferably includes SiO.

Next, a part of the protection film 402 is removed to expose at least a part of the protection film 401. In the process of removing a part of the protection film 402, it is preferable to planarize the protection film 402 with a chemical-mechanical polishing (CMP) method. With this configuration, bonding defects on the substrate to be bonded in the subsequent process can be reduced.

The protection film 401 including nitrogen is located between the protection film 402 and the semiconductor layer 201 and the CMP process is performed to expose the protection film 401, thereby making it possible to increase the flatness within the wafer surface due to a polishing rate difference between the materials.

In the first exemplary embodiment, the CMP process is performed to expose the protection film 401, and then the process of removing the protection film 401 by, for example, etching is performed. Next, the thickness of the semiconductor layer 201 is reduced by wet etching. In this case, it is desirable to provide a first region obtained by adding an impurity to the semiconductor layer 201 in advance, and a second region to which the impurity is not added. This configuration makes it possible to control the etching rate for the semiconductor layer 201 between the first region and the second region and to process the semiconductor layer 201 so as to have a specific thickness.

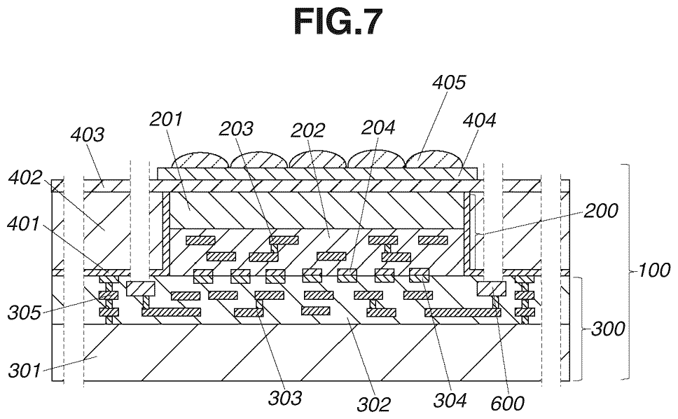

To prevent the semiconductor layer 201 from being etched from a lateral direction during wet etching, it is desirable for the insulating film including the protection film 401 to protect a side wall of the semiconductor layer 201. In this case, the insulating film including the protection film 401 is desirably left at a location higher than the location of the semiconductor layer 201 at least after wet etching. Thereafter, a part of the protection film 401 is removed by etching such that an upper end of the protection film 401 becomes lower than an upper end of the semiconductor layer 201. Next, the CMP process is performed to reduce the thickness of the semiconductor layer 201 to, for example, 1 μm (micrometers) to 5 μm. In this case, a part of the protection film 401 and a part of the protection film 402 are removed at once. As illustrated in FIG. 7, the protection film 401 is located so as to cover the side surface of the substrate 200 and the top surface of the substrate 300. If the protection film 401 is higher than the semiconductor layer 201 during the CMP process, the protection film 401 with a narrower width can be bent during polishing and a physical flaw can be generated on the semiconductor layer 201. Thus, it is desirable to etch the protection film 401 prior to the CMP process.

Next, as illustrated in FIG. 7, optical structures such as the color filter 404 and the microlenses 405 are formed on the semiconductor layer 201 to form openings to expose the pads 600, and the wafer is diced into individual chips, thereby obtaining the semiconductor apparatus 100 as illustrated in FIGS. 1A and 1B.

During a period between the process of reducing the thickness of the semiconductor layer 201 and the process of forming the optical structures, a bonding layer 403 can be formed. The bonding layer 403 can include, for example, SiO or SiON. With this configuration, the optical structures and the semiconductor layer 201 can be bonded to each other. Between the bonding layer 403 and the semiconductor layer 201, an oxide film, a metallic wiring layer having a light-shielding function, or the like can also be located. A part of the bonding layer 403 can also have an interlayer lens shape.

In the semiconductor apparatus according to the first exemplary embodiment, the protection film 401 extends from at least a part of the side surface of the semiconductor layer 201 to at least a part of the side surface of the wiring structure 260. With this configuration, the intrusion of moisture or the like into the semiconductor layer 201 can be easily reduced and the reliability of the semiconductor apparatus can be easily ensured. The manufacturing method of the semiconductor apparatus according to the first exemplary embodiment makes it possible to reduce bonding defects on the substrate to be bonded.

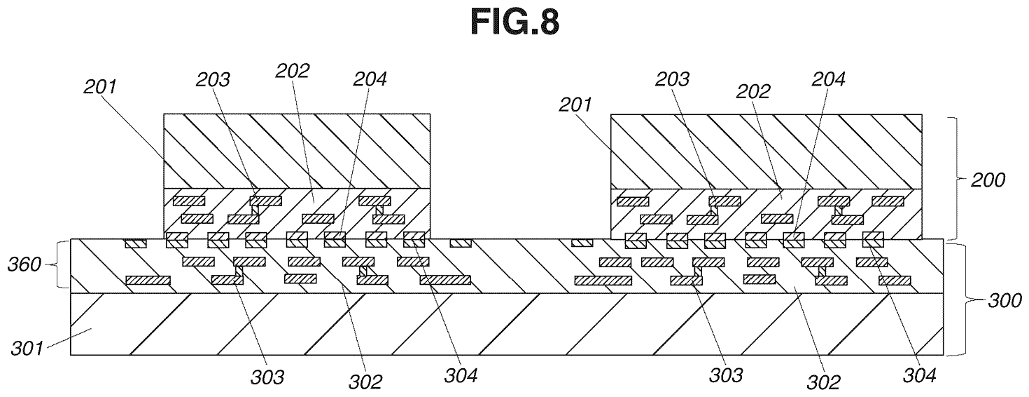

A semiconductor apparatus and a manufacturing method of the semiconductor apparatus according to a second exemplary embodiment of the present disclosure will now be described with reference to FIGS. 8 to 10. FIGS. 8 to 10 are process cross-sectional views each illustrating the manufacturing method of the semiconductor apparatus according to the second exemplary embodiment. The second exemplary embodiment differs from the first exemplary embodiment in that the metal layer serving as each pad 600 is not formed in the wiring structure 360 in the process of forming the bonded body obtained by bonding the substrate 300 in the wafer state to the chip-shaped substrate 200. The second exemplary embodiment is substantially the same as the first exemplary embodiment except for the above-described and below-described differences, and thus the description thereof may be omitted.

As illustrated in FIG. 8, a bonded body is formed which is obtained by stacking and bonding the chip-shaped substrate 200 onto the substrate 300 in the wafer state. The semiconductor layer 201 of the substrate 200 includes a photoelectric conversion element.

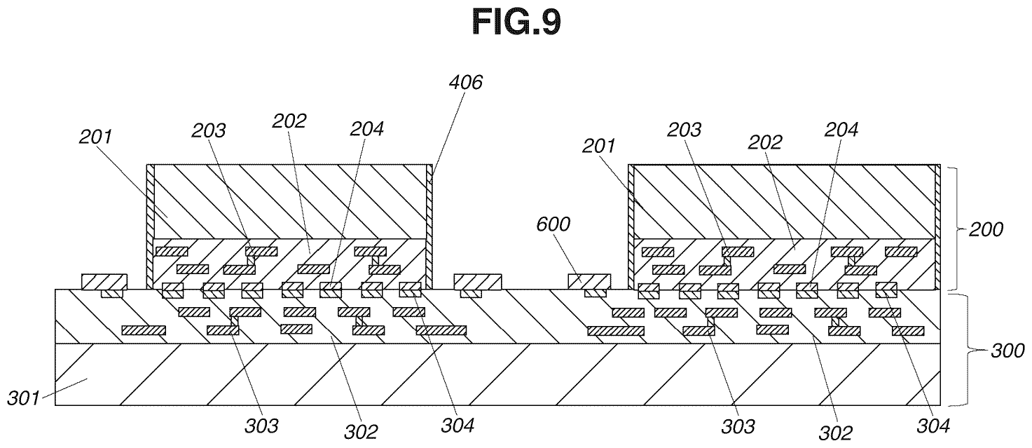

Next, as illustrated in FIG. 9, silicon oxide is deposited and etched to form a protection structure 406 on a side surface of the semiconductor layer 201. Next, a metal film composed mainly of aluminum is deposited and the metal layer of each pad 600 including nitrogen is formed by the photolithography technique and the etching technique. In this case, each pad 600 is in contact with the metal pattern 304 and thus is electrically connected to the metal pattern 304.

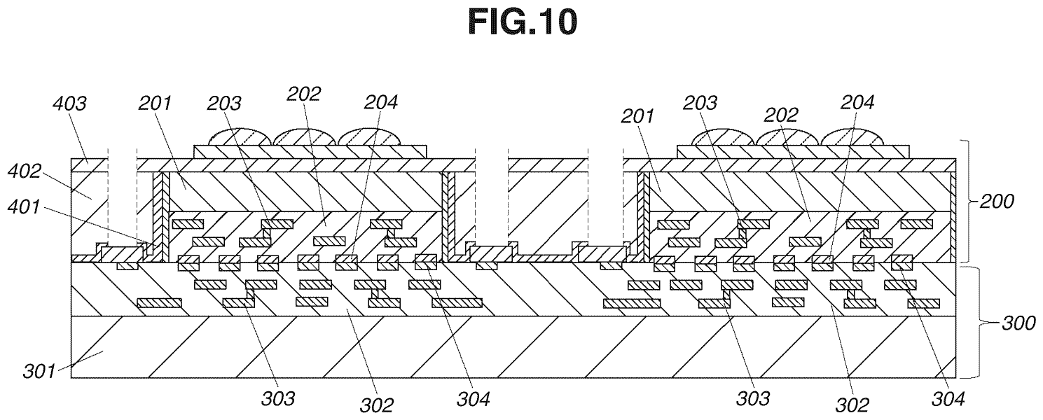

Thereafter, as illustrated in FIG. 10, the protection film 401 and the protection film 402 are formed and the thickness of the semiconductor layer 201 is reduced to thereby form optical structures, similarly to the first exemplary embodiment. The bonding layer 403, the protection film 402, and the protection film 401 are etched to form openings to expose the pads 600, and the wafer is diced into individual chips, thereby obtaining the semiconductor apparatus illustrated in FIG. 10.

The metal layer of each pad 600 has a thickness greater than the thickness of other metal layers, which may lead to deterioration in the flatness during formation. In the second exemplary embodiment, the pads 600 are formed after the chip-shaped substrate 200 is bonded to the substrate 300 in the wafer state, thereby making it possible to reduce bonding defects during bonding of the substrate 300 and the substrate 200 and to reduce a failure in the electrical connection between the metal patterns 204 and 304.

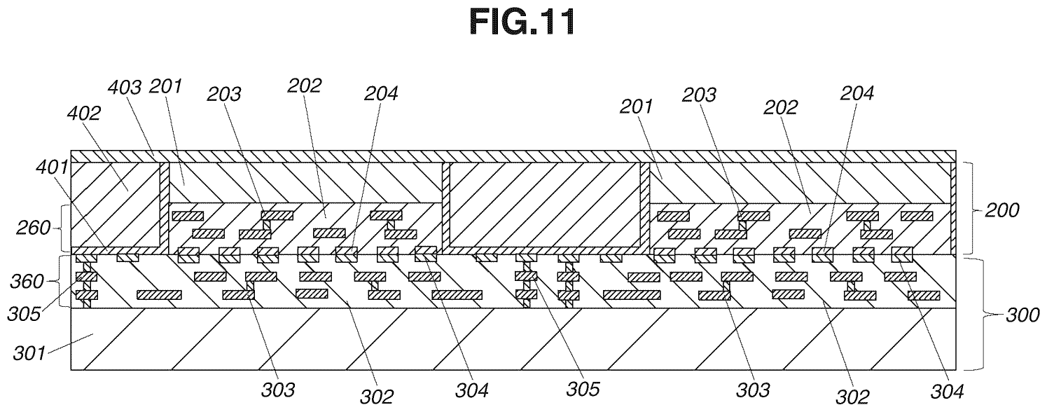

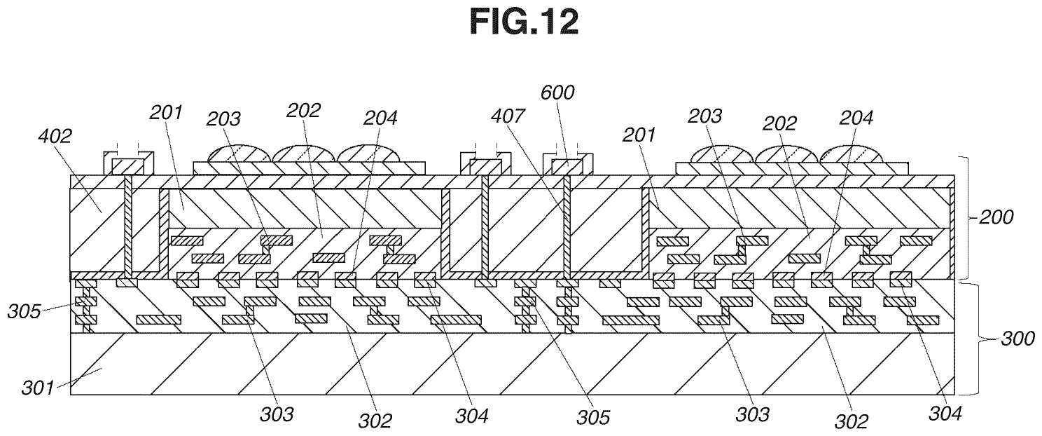

A semiconductor apparatus and a manufacturing method of the semiconductor apparatus according to a third exemplary embodiment of the present disclosure will now be described with reference to FIGS. 11 and 12. FIGS. 11 and 12 are process cross-sectional views each illustrating the manufacturing method of the semiconductor apparatus according to the third exemplary embodiment. The third exemplary embodiment differs from the first exemplary embodiment in that the metal layer serving as each pad 600 is not formed in the wiring structures 260 and 360 in the state where the layers up to the bonding layer 403 are formed and the pads 600 are formed above the top surface of the wiring structure 260. The third exemplary embodiment is substantially the same as the first exemplary embodiment except for the above-described and below-described differences, and thus the description thereof may be omitted.

As illustrated in FIG. 11, a bonded body obtained by stacking and bonding the chip-shaped substrate 200 onto the substrate 300 in the wafer state is formed. The semiconductor layer 201 of the substrate 200 includes a photoelectric conversion element. Similarly to the first exemplary embodiment, the protection film 401 and the protection film 402 are formed, and thickness of the semiconductor layer 201 is reduced to thereby form the bonding layer 403 included in the optical structures.

Next, as illustrated in FIG. 12, openings each having a via hole shape are formed in the bonding layer 403, the protection film 402, and the protection film 401, and metal composed mainly of tungsten is buried in the openings, thereby forming plugs 407. Further, the pads 600 each composed mainly of aluminum are formed to contact with the plugs 407. Thereafter, a color filter, microlens, and the like included in the optical structures are formed to thereby obtain the semiconductor apparatus illustrated in FIG. 12.

In the third exemplary embodiment, the plugs 407 are connected to the metal pattern 304, but instead can be connected to the metal layer of any one of the wiring layers 303. In the third exemplary embodiment, the chip-shaped substrate 200 is bonded to the substrate 300 and then the pads 600 are formed, thereby reducing bonding defects during bonding the substrate 300 and the substrate 200 and reducing a failure in the electrical connection between the metal pattern 204 and the metal pattern 304.

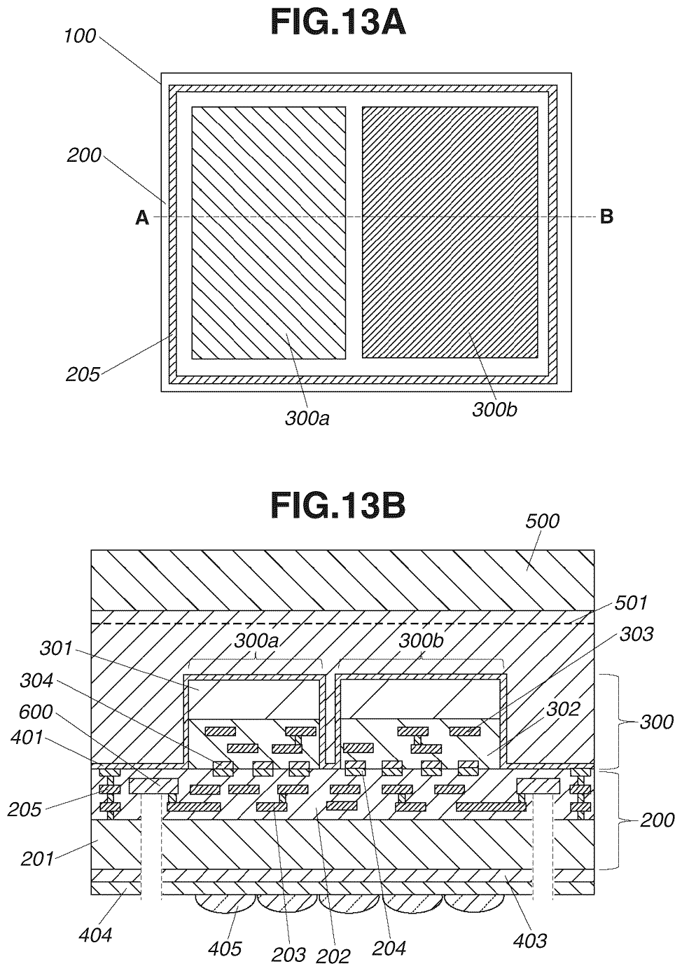

A semiconductor apparatus and a manufacturing method of the semiconductor apparatus according to a fourth exemplary embodiment of the present disclosure will now be described with reference to FIGS. 13A to 18.

A schematic configuration of the semiconductor apparatus according to the fourth exemplary embodiment will be described with reference to FIGS. 13A and 13B. FIG. 13A is a schematic plan view of the semiconductor apparatus according to the fourth exemplary embodiment, and FIG. 13B is a schematic cross-sectional view of the semiconductor apparatus taken along a line A-B illustrated in FIG. 13A.

The fourth exemplary embodiment differs from the first exemplary embodiment in that a circuit unit serving as the chip-shaped substrate 300 (first substrate) is bonded to the substrate 200 (second substrate) in the wafer state and the substrate 200 includes a guard structure 205. The substrate 300 including a memory circuit 300a and a logic circuit 300b as individual chips is bonded to one image sensor included in the substrate 200.

The fourth exemplary embodiment is substantially the same as the first exemplary embodiment except for the above-described and below-described differences, and thus the description thereof may be omitted.

In the fourth exemplary embodiment, the semiconductor layer 201 of the substrate 200 is larger than the semiconductor layer 301 of the substrate 300 in a planar view.

The substrate 200 includes the guard structure 205. The guard structure 205 is similar to the guard structure 305 described in the first exemplary embodiment. The guard structure 205 includes a metal pattern on the bonded surface to be bonded to the substrate 300. The metal pattern of the guard structure 205 is covered with the protection film 401. This configuration makes it possible to prevent the diffusion of the metal element of the metal pattern of the guard structure 205 to the semiconductor layer 301. At least a part of the guard structure 205 is formed outside of the memory circuit 300a and the logic circuit 300b in a planar view.

On a surface of the substrate 300 that is opposite to the substrate 200, a support substrate 500 is located. Similarly to the first exemplary embodiment, on a surface of the substrate 200 that is opposite to the substrate 300, the bonding layer 403 and optical structures such as the color filter 404 and the microlenses 405 are located.

The protection film 401 is located not only on the guard structure 205, but also on the side surface of the substrate 300 and the surface of the substrate 300 that is opposite to the bonded surface. As illustrated in FIG. 13B, the protection film 401 is desirably located to continuously cover surfaces other than the bonded surface to be bonded to the substrate 200. In the example illustrated in FIG. 13B, the protection film 401 covers the side surfaces of the memory circuit 300a and the logic circuit 300b and the surface opposite to the bonded surface to be bonded to the substrate 200.

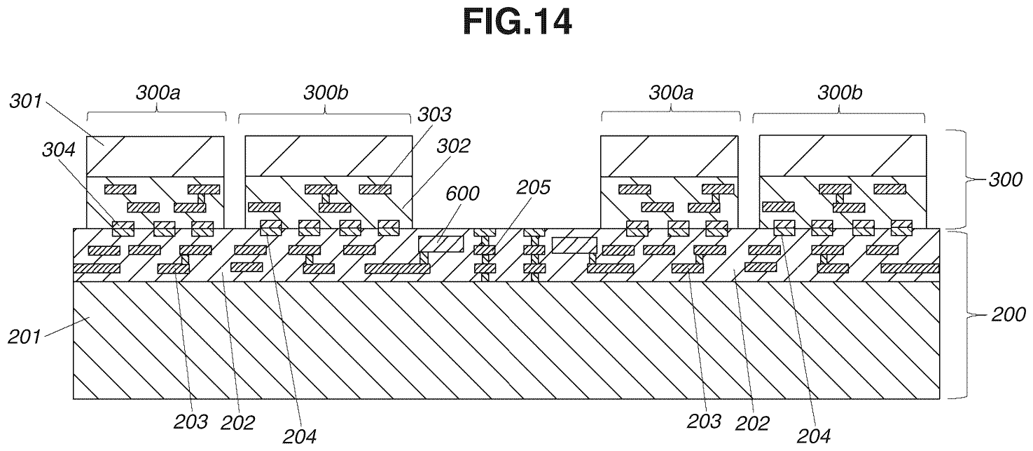

Next, the manufacturing method of the semiconductor apparatus according to the fourth exemplary embodiment will be described with reference to FIGS. 14 to 18. FIGS. 14 to 18 are process cross-sectional views each illustrating the manufacturing method of the semiconductor apparatus according to the fourth exemplary embodiment.

As illustrated in FIG. 14, the substrate 300 including the chip-shaped memory circuit 300a and the logic circuit 300b is bonded to the substrate 200 in the wafer state in which a plurality of image sensors is located. In the fourth exemplary embodiment, two circuit chips are bonded to one image sensor, but only one circuit chip can be bonded, or three or more circuit chips can be bonded. The memory circuit 300a and the logic circuit 300b are bonded by Cu—Cu metal bonding and covalent bonding between the wiring interlayer film 202 and the wiring interlayer film 302, similarly to the first exemplary embodiment. After the chips are bonded, the process of reducing the thickness of the semiconductor layer 301 can also be performed. At least a part of the guard structure 205 is formed outside of the memory circuit 300a and the logic circuit 300b in a planar view. The metal layer serving as each pad 600 is formed in the wiring interlayer film 202 in the substrate 200.

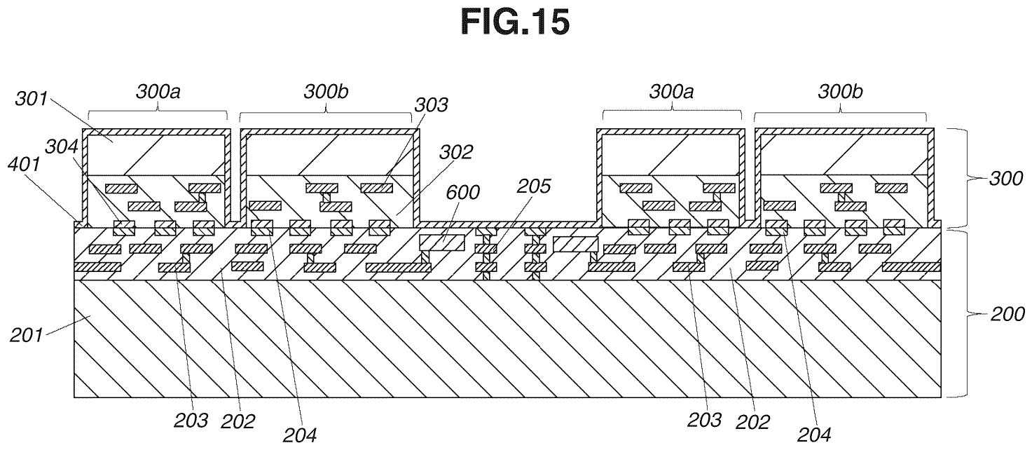

Next, as illustrated in FIG. 15, SiN is deposited as the protection film 401. Similarly to the first exemplary embodiment, not only SiN, but also SiON and the like are desirably used as a material for the protection film 401 in terms of improvement in moisture resistance. In the fourth exemplary embodiment, the protection film 401 is left on the side surface and the top surface of each of the memory circuit 300a and the logic circuit 300b, thereby making it possible to improve the moisture resistance of the memory circuit 300a and the logic circuit 300b.

Similarly to the first exemplary embodiment, the process of removing a part of the SiN region serving as the protection film 401 can also be performed. In the case of removing a part of the SiN region, for example, the protection film 401 is removed from the dicing surface, so that a failure such as peeling of the film or the like during dicing can be avoided.

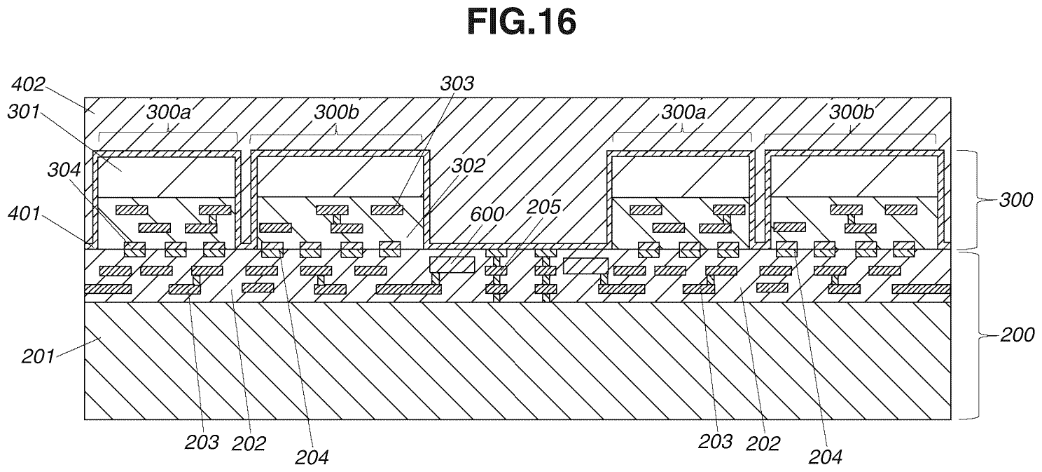

Next, as illustrated in FIG. 16, for example, an insulating film including silicon oxide is deposited by chemical vapor deposition (CVD) and is planarized by CMP, to thereby form the protection film 402. The substrate 300 has a thickness of, for example, 10 μm to 30 μm, and it is desirable to deposit the protection film 402 with a film thickness greater than the height of the substrate 300. In the case of forming the insulating film of the protection film 402, the insulating film can be deposited by a method using coating such as a spin-on-glass method. In such a case, the flatness can be improved. After the insulating film is deposited by the spin-on-glass method, the insulating film can be continuously deposited by CVD and then planarization can be performed by CMP. In the process of planarizing the protection film 402, the CMP process is performed to expose the portion formed on the substrate 300 of the protection film 401, thereby making it possible to increase the flatness within the wafer surface due to the polishing rate difference between the materials. In the planarization process, it is not necessary to expose the protection film 401, and the protection film 402 can also be left on the entire surface. Prior to the deposition of the protection film 402, for example, an underfill material can be formed by spin coating, and then a protection film formed of a silicon oxide film can be deposited and the protection film 402 can be planarized. The introduction of the underfill material can improve the flatness after the CMP process.

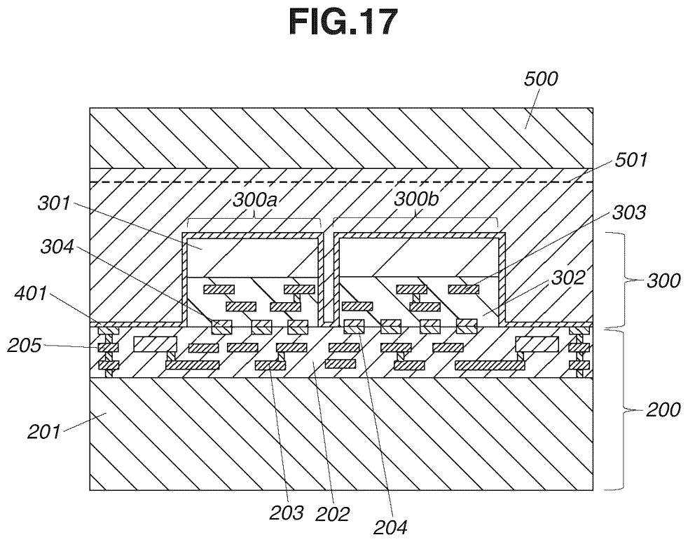

Next, as illustrated in FIG. 17, the support substrate 500 is bonded via a bonded surface 501. The support substrate 500 is provided with bonding layers made of SiN or SiON. On the bonded surface 501, the bonding layers made of SiN or SiON are bonded together.

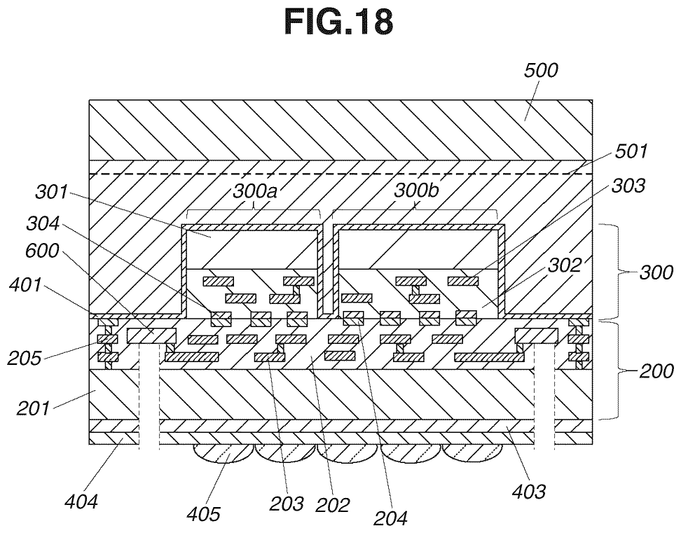

Next, as illustrated in FIG. 18, the process of reducing the thickness of the semiconductor layer 201 is performed to form optical structures such as the color filter 404 and the microlenses 405. Next, openings are formed to expose the pads 600. The manufacturing method of the semiconductor apparatus according to the fourth exemplary embodiment makes it possible to reduce bonding defects on the support substrate or the like.

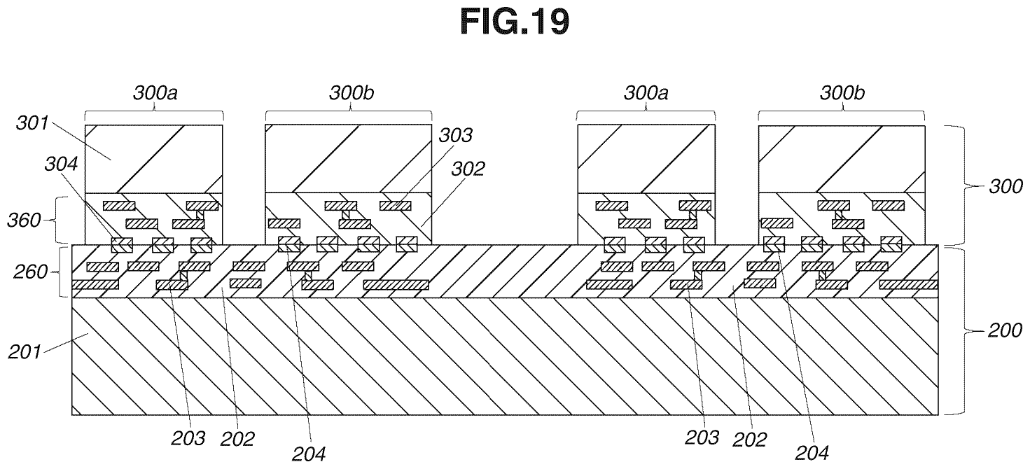

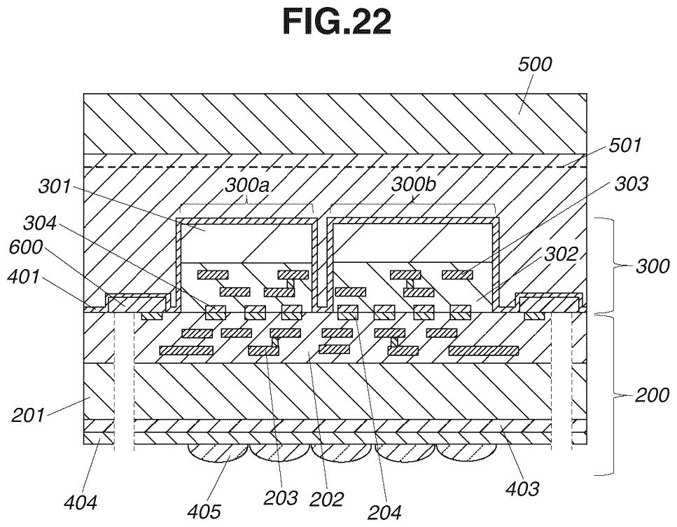

A semiconductor apparatus and a manufacturing method of the semiconductor apparatus according to a fifth exemplary embodiment of the present disclosure will now be described with reference to FIGS. 19 and 22. FIGS. 19 to 22 are process cross-sectional views each illustrating the manufacturing method of the semiconductor apparatus according to the fifth exemplary embodiment. The fifth exemplary embodiment differs from the fourth exemplary embodiment in that the metal layer serving as each pad 600 is not formed in the wiring structure 260 in the process of forming the bonded body obtained by bonding the substrate 200 in the wafer state to the chip-shaped substrate 300. The fifth exemplary embodiment is substantially the same as the fourth exemplary embodiment except for the above-described difference and the following differences, and thus the description thereof may be omitted.

As illustrated in FIG. 19, a bonded body obtained by bonding a circuit unit serving as the chip-shaped substrate 300 (first substrate) to the substrate 200 in the wafer state is formed. The metal layer serving as each pad 600 is not formed in the wiring interlayer film 202.

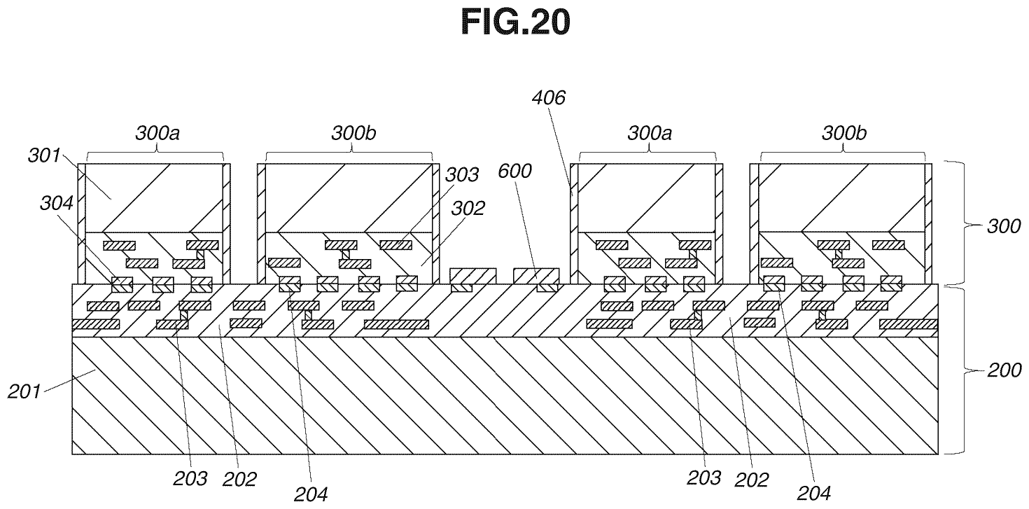

Next, as illustrated in FIG. 20, silicon oxide is deposited and etched to thereby form the protection structure 406 on a side surface of the semiconductor layer 301. Next, a metal film composed mainly of aluminum is deposited, and the metal layer of each pad 600 including nitrogen is formed by the photolithography technique and the etching technique. In this case, the metal layer of each pad 600 is in contact with the metal pattern 204 and thus is electrically connected to the metal pattern 204. In the fifth exemplary embodiment, each pad 600 is connected to the metal pattern 204, but instead can also be connected to the wiring layer 203 via a via hole or the like.

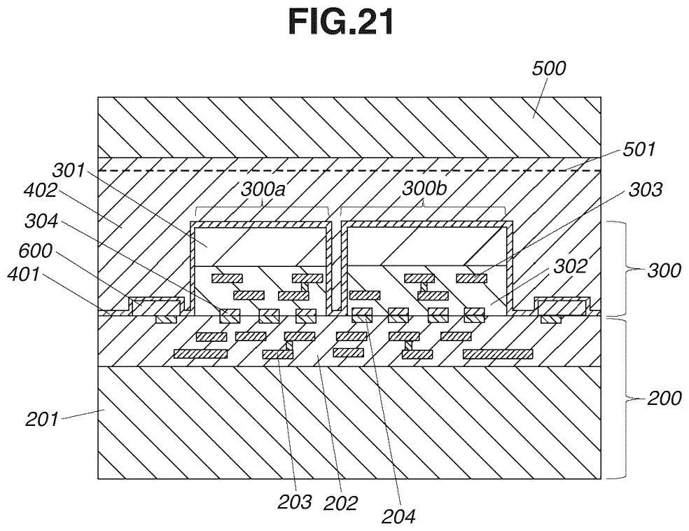

Next, the semiconductor layer 301 is processed to reduce the thickness of the semiconductor layer 301 by a backgrinding apparatus, and the protection film 401 and the protection film 402 are formed as illustrated in FIG. 21, and then the support substrate 500 is bonded via the bonded surface 501.

Next, as illustrated in FIG. 22, the process of reducing the thickness of the semiconductor layer 201 is performed to thereby form the optical structures such as the color filter 404 and the microlenses 405. Next, openings are formed to expose the pads 600, thereby obtaining the semiconductor apparatus illustrated in FIG. 22.

In the fifth exemplary embodiment, the chip-shaped substrate 300 is bonded to the substrate 200 in the wafer shape and then the pads 600 are formed, thereby making it possible to reduce bonding defects during bonding of the substrate 300 and the substrate 200 and to reduce a failure in the electrical connection between the metal pattern 204 and the metal pattern 304.

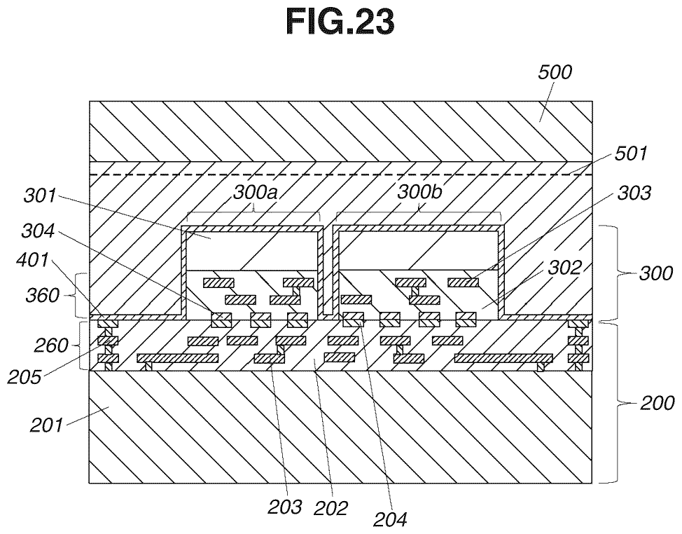

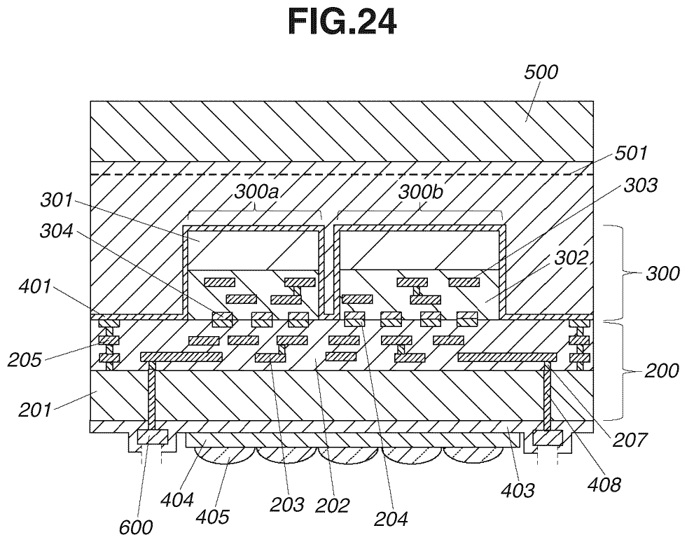

A semiconductor apparatus and a manufacturing method of the semiconductor apparatus according to a sixth exemplary embodiment of the present disclosure will be described with reference to FIGS. 23 and 24. FIGS. 23 and 24 are process cross-sectional views each illustrating the manufacturing method of the semiconductor apparatus according to the sixth exemplary embodiment. The sixth exemplary embodiment differs from the fourth exemplary embodiment in that the metal layer serving as each pad 600 is not formed in the wiring structure 260 in the process of bonding the substrate 200 in the wafer state to the chip-shaped substrate 300 and bonding the support substrate 500. The sixth exemplary embodiment is substantially the same as the fourth exemplary embodiment except for the above-described and below-described differences, and thus the description thereof may be omitted.

As illustrated in FIG. 23, a circuit unit serving as the chip-shaped substrate 300 (first substrate) is bonded to the substrate 200 in the wafer state, and is further bonded to the support substrate 500. As illustrated in FIG. 23, the metal layer serving as each pad 600 is not formed in the wiring interlayer film 202 of the wiring structure 260 according to the sixth exemplary embodiment.

In the sixth exemplary embodiment, as illustrated in FIG. 24, the process of reducing the thickness of the semiconductor layer 201 is performed and a part of the bonding layer 403 is formed, and then via holes 408 that penetrate through the semiconductor layer 201 are formed. The via holes 408 are respectively bonded to via holes 207 formed in the wiring layers 203. Next, the metal patterns of the pads 600 are formed, the remaining part of the bonding layer 403 is formed, and then openings for the respective pads 600 are formed.

In the sixth exemplary embodiment, the via holes 408 are bonded to the via holes 207, but instead can be bonded to the wiring layers 203. Next, the optical structures such as the color filter 404 and the microlenses 405 are formed and the pads 600 are formed, thereby obtaining the semiconductor apparatus illustrated in FIG. 24.

In the sixth exemplary embodiment, the chip-shaped substrate 300 is bonded to the substrate 200 in the wafer shape and then the pads 600 are formed, thereby making it possible to reduce bonding defects during bonding of the substrate 300 and the substrate 200 and to reduce a failure in the electrical connection between the metal pattern 204 and the metal pattern 304.

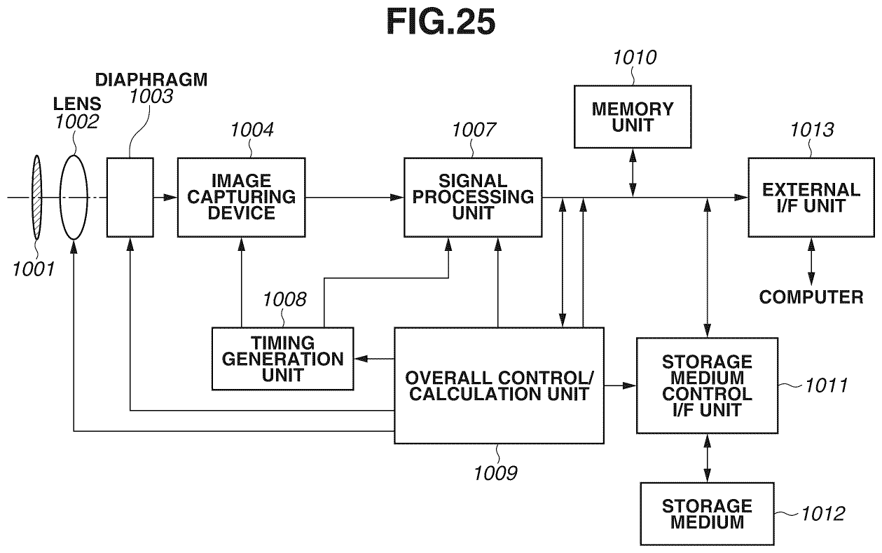

A photoelectric conversion system according to a seventh exemplary embodiment will be described with reference to FIG. 25. FIG. 25 is a block diagram illustrating a schematic configuration of the photoelectric conversion system according to the seventh exemplary embodiment.

The semiconductor apparatuses (image capturing apparatuses) described in the first to sixth exemplary embodiments are applicable to various photoelectric conversion systems. Examples of various applicable photoelectric conversion systems include a digital still camera, a digital camcorder, a monitoring camera, a copying machine, a facsimile machine, a mobile phone, an on-vehicle camera, and an observation satellite. Various applicable photoelectric conversion systems also include a camera module including an optical system such as a lens and an image capturing apparatus. FIG. 25 is a block diagram illustrating a digital still camera as an example of such photoelectric conversion systems.

The photoelectric conversion system illustrated in FIG. 25 includes an image capturing apparatus 1004 serving as an example of the semiconductor apparatus, and a lens 1002 for causing the image capturing apparatus 1004 to form an optical image of a subject. The photoelectric conversion system further includes a diaphragm 1003 for changing the amount of light to pass through the lens 1002, and a barrier 1001 for protecting the lens 1002. The lens 1002 and the diaphragm 1003 are optical systems for focusing light on the image capturing apparatus 1004. The image capturing apparatus 1004 is any one of the semiconductor apparatuses (image capturing apparatuses) according to the exemplary embodiments described above, and converts the optical image formed by the lens 1002 into an electric signal.

The photoelectric conversion system further includes a signal processing unit 1007 serving as an image generation unit for generating an image by performing processing on an output signal output from the image capturing apparatus 1004. The signal processing unit 1007 performs an operation of performing various correction and compression processes, as needed, and outputting image data. The signal processing unit 1007 can be formed in a semiconductor substrate provided with the image capturing apparatus 1004, or can also be formed in another semiconductor substrate different from the semiconductor substrate provided with the image capturing apparatus 1004. The image capturing apparatus 1004 and the signal processing unit 1007 can also be formed in the same semiconductor substrate.

The photoelectric conversion system further includes a memory unit 1010 for temporarily storing image data, and an external interface (I/F) unit 1013 for communicating with an external computer or the like. The photoelectric conversion system also includes a storage medium 1012, such as a semiconductor memory, for storing or reading out image capturing data, and a storage medium control I/F unit 1011 for storing data in the storage medium 1012 or reading out data from the storage medium 1012. The storage medium 1012 can also be incorporated in or detachably attached to the photoelectric conversion system.

The photoelectric conversion system also includes an overall control/calculation unit 1009 that controls various arithmetic operations and the entire digital still camera, and a timing generation unit 1008 that outputs various timing signals to the image capturing apparatus 1004 and the signal processing unit 1007. In this case, the timing signals and the like can be input from an external apparatus. The photoelectric conversion system can include at least the image capturing apparatus 1004 and the signal processing unit 1007 that processes the output signals output from the image capturing apparatus 1004.

The image capturing apparatus 1004 outputs an image capturing signal to the signal processing unit 1007. The signal processing unit 1007 performs predetermined signal processing on the image capturing signal output from the image capturing apparatus 1004, and outputs image data. The signal processing unit 1007 generates an image using the image capturing signal.

As described above, according to the seventh exemplary embodiment, a photoelectric conversion system can be achieved to which any one of the semiconductor apparatuses (image capturing apparatuses) according to the exemplary embodiments described above is applied.

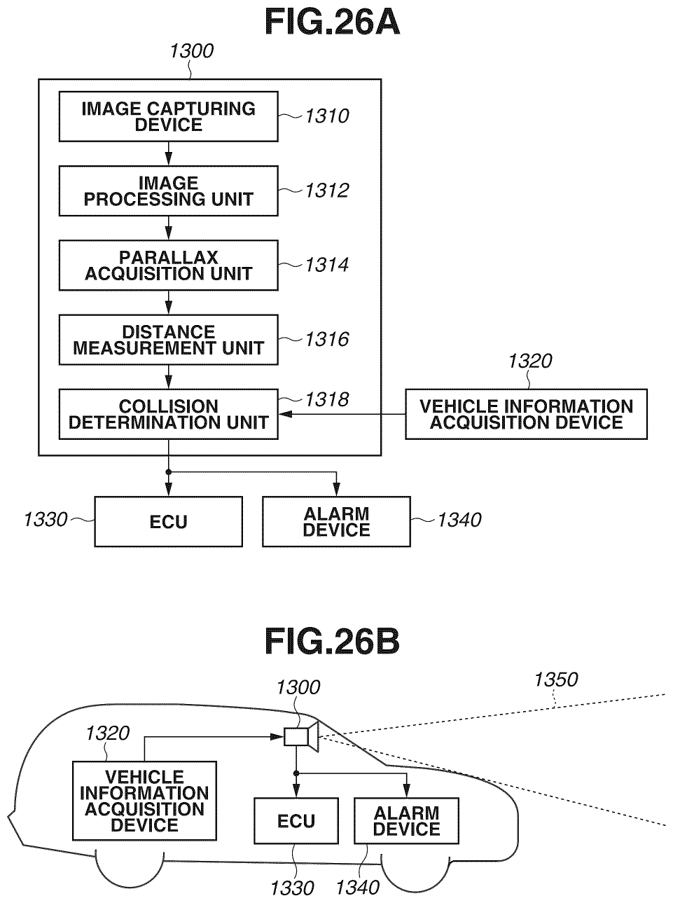

A photoelectric conversion system and a moving body according to an eighth exemplary embodiment will be described with reference to FIGS. 26A and 26B. FIGS. 26A and 26B illustrate configurations of the photoelectric conversion system and the moving body according to the eighth exemplary embodiment.

FIG. 26A illustrates an example of the photoelectric conversion system for an on-vehicle camera. A photoelectric conversion system 1300 includes an image capturing apparatus 1310. The image capturing apparatus 1310 is any one of the semiconductor apparatuses (image capturing apparatuses) according to the exemplary embodiments described above. The photoelectric conversion system 1300 also includes an image processing unit 1312 that performs image processing on a plurality of pieces of image data acquired by the image capturing apparatus 1310. The photoelectric conversion system 1300 also includes a parallax acquisition unit 1314 that calculates a parallax (phase difference between parallax images) from the plurality of pieces of image data acquired by the photoelectric conversion system 1300. The photoelectric conversion system 1300 also includes a distance measurement unit 1316 that calculates a distance to an object based on the calculated parallax, and a collision determination unit 1318 that determines whether there is a possibility of collision based on the calculated distance. In here, the parallax acquisition unit 1314 and the distance measurement unit 1316 are examples of a distance information acquisition unit configured to acquire distance information about a distance to an object. Specifically, the distance information is information about a parallax, a defocus amount, a distance to an object, or the like. The collision determination unit 1318 can determine the possibility of collision using any one of these pieces of distance information. The distance information acquisition unit can be implemented by exclusively designed hardware or a software module. The distance information acquisition unit can also be implemented by a field programmable gate array (FPGA), an application-specific integrated circuit (ASIC), or the like, or a combination thereof.

The photoelectric conversion system 1300 is connected to a vehicle information acquisition apparatus 1320, and is configured to acquire vehicle information such as a vehicle speed, a yaw rate, and a steering angle. The photoelectric conversion system 1300 is connected to an engine control unit (ECU) 1330 as a control unit that outputs, on the basis of a determination result from the collision determination unit 1318, a control signal for causing the vehicle to generate a braking force. The photoelectric conversion system 1300 is also connected to an alarm apparatus 1340 that issues an alarm to a driver based on the determination result from the collision determination unit 1318. For example, if there is a high possibility of collision based on the determination result from the collision determination unit 1318, the ECU 1330 performs vehicle control to avoid a collision or reduce damage by applying a brake, releasing the accelerator, controlling the engine output, or the like. The alarm apparatus 1340 alerts a user by going off an alarm such as sound, displaying alarm information on the screen of, for example, a car navigation system, or vibrating the seat belt or the steering wheel.

In the eighth exemplary embodiment, the photoelectric conversion system 1300 captures images around the vehicle, for example, images of views in front of or behind the vehicle. FIG. 26B illustrates the photoelectric conversion system 1300 in a case of capturing images of views in front of the vehicle (image capturing range 1350). The vehicle information acquisition apparatus 1320 sends an instruction to the photoelectric conversion system 1300 or the image capturing apparatus 1310. With such a configuration, the accuracy of ranging can be improved.

The exemplary embodiment described above illustrates an example of control for preventing a vehicle from colliding with another vehicle. The photoelectric conversion system 1300 can also be applied to, for example, control for automatic driving so as to follow other vehicles or control for automatic driving so as not to drive out of the lane. The photoelectric conversion system 1300 can be applied not only to vehicles such as automobiles, but also to, for example, a moving body (moving apparatus) such as a vessel, an airplane, or an industrial robot. Such a moving body includes one or both of a driving force generation unit that generates a driving force to be mainly used for movement of the moving body, and a rotary member to be mainly used for movement of the moving body. The driving force generation unit can be an engine, a motor, or the like. The rotary member can be a tire, a wheel, a screw of a vessel, a propeller of a flight vehicle, or the like. The photoelectric conversion system 1300 can be applied not only to moving bodies, but also to a wide range of apparatuses using object recognition such as an intelligent transportation system (ITS).

The present disclosure is not limited only to the above-described exemplary embodiments and can be modified in various ways.

For example, an example where a part of the configuration according to any of the exemplary embodiments is added to any of the other exemplary embodiments, and an example where a part of the configuration according to any of the exemplary embodiments is replaced with a part of the configuration according to any of the other exemplary embodiments are also included in the exemplary embodiments of the present disclosure.

The photoelectric conversion systems described in the seventh and eighth exemplary embodiments are merely examples of a photoelectric conversion system to which the semiconductor apparatus according to the present disclosure can be applied. The photoelectric conversion system to which the semiconductor apparatus according to the present disclosure can be applied is not limited only to the configurations illustrated in FIG. 25 and FIGS. 26A and 26B.

The above-described exemplary embodiments are merely specific examples for carrying out the present disclosure. The technical scope of the present disclosure should not be interpreted in a limited way. That is, the present disclosure can be carried out in various forms without departing from the technical idea or the main features thereof.

The disclosed content of the present specification includes complementary sets of concepts described in the present specification. Specifically, if there is a description in the present specification to the effect that “A is B” (A=B), for example, it is assumed that the present specification discloses to the effect that “A is not B” (A/B), even if a description to the effect that “A is not B” (A≠B) is omitted. This is because it is a premise that a description to the effect that “A is B” takes into consideration a case of “A is not B”.

The above-described exemplary embodiments can be modified as appropriate without departing from the technical idea of the present disclosure. The disclosed content of the present specification encompasses not only what is described in this specification but also all matters that can be recognized from the present specification and the drawings attached to this specification. The disclosed content of the present specification includes complementary sets of concepts described in this specification. In other words, if there is a description in this specification to the effect that “A is larger than B”, for example, it can be said that this specification discloses that “A is not larger than B” even if the description “A is not larger than B” is omitted. This is because the description “A is larger than B” is based on the premise that the case of “A is not larger than B” is taken into account.

According to an aspect of the present disclosure, it is possible to reduce degradation in the function of a semiconductor apparatus due to moisture or the like intruding into the semiconductor apparatus. Further, a semiconductor apparatus manufacturing method according to another aspect of the present disclosure makes it possible to reduce bonding defects on a substrate to be bonded.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Applications No. 2024-050944, filed Mar. 27, 2024, and No. 2024-231796, filed Dec. 27, 2024, which are hereby incorporated by reference herein in their entirety.

What is claimed is:

1. A semiconductor apparatus comprising:
a first substrate including a first wiring structure and a first semiconductor layer;
a second substrate including a second wiring structure and a second semiconductor layer; and
a pad to be connected to an external terminal,
wherein a first metal pattern included in the first wiring structure and a second metal pattern included in the second wiring structure are bonded to electrically connect the first semiconductor layer and the second semiconductor layer,
wherein the second semiconductor layer is larger than the first semiconductor layer in a plan view seen from a side with the first semiconductor layer,
wherein the pad is located outside of the first semiconductor layer in the plan view,
wherein a first protection film extends to at least a part of a side surface of the first semiconductor layer and at least a part of a side surface of the first wiring structure, and
wherein the first protection film includes nitrogen.

2. The semiconductor apparatus according to claim 1, wherein the first protection film includes silicon nitride or silicon oxynitride.

3. The semiconductor apparatus according to claim 2, wherein the first protection film is located on an entire side surface of the first semiconductor layer.

4. The semiconductor apparatus according to claim 3, wherein, in the planar view, the first protection film overlaps the second wiring structure located outside of the first semiconductor layer.

5. The semiconductor apparatus according to claim 1,
wherein the second wiring structure includes a guard structure having a third metal pattern located at a same height where the second metal pattern, and
wherein, in the planar view, a contact portion of the first protection film that is in contact with the third metal pattern is located outside of the first semiconductor layer.

6. The semiconductor apparatus according to claim 5, wherein, in the planar view, the contact portion is located outside of an edge of the first semiconductor layer.

7. The semiconductor apparatus according to claim 6, wherein the third metal pattern is made of a material composed mainly of copper.

8. The semiconductor apparatus according to claim 1, wherein the first protection film extends to a surface of the first semiconductor layer that is opposite to the second semiconductor layer.

9. The semiconductor apparatus according to claim 1, wherein an insulating film is located between the side surface of the first semiconductor layer and the first protection film.

10. The semiconductor apparatus according to claim 1, wherein a shortest distance between the side surface of the first semiconductor layer and the first protection film is 300 nm or less.

11. The semiconductor apparatus according to claim 1, further comprising a support substrate,
wherein the first substrate and the second substrate are stacked on the support substrate.

12. The semiconductor apparatus according to claim 1, wherein the first semiconductor layer includes a photoelectric conversion element.

13. The semiconductor apparatus according to claim 1, wherein the second semiconductor layer includes a photoelectric conversion element.

14. The semiconductor apparatus according to claim 1, wherein the pad is located at a height where the first wiring structure is located.

15. The semiconductor apparatus according to claim 1, wherein the pad is located above the first semiconductor layer.

16. A semiconductor apparatus comprising:
a first substrate including a first wiring structure and a first semiconductor layer including a photoelectric conversion element; and
a second substrate including a second wiring structure and a second semiconductor layer,
wherein a first metal pattern included in the first wiring structure and a second metal pattern included in the second wiring structure are bonded together to electrically connect the first semiconductor layer and the second semiconductor layer to each other,
wherein the second semiconductor layer is larger than the first semiconductor layer in a plan view seen from a side with the first semiconductor layer,
wherein a first protection film extends to at least a part of a side surface of the first semiconductor layer and at least a part of a side surface of the first wiring structure, and
wherein the first protection film includes nitrogen.

17. The semiconductor apparatus according to claim 16, wherein the first protection film includes silicon nitride or silicon oxynitride.

18. The semiconductor apparatus according to claim 17, wherein the first protection film is located on an entire side surface of the first semiconductor layer.

19. The semiconductor apparatus according to claim 18, wherein the first protection film overlaps the second wiring structure located outside of the first semiconductor layer in the plan view.

20. The semiconductor apparatus according to claim 16,
wherein the second wiring structure includes a guard structure including a third metal pattern located at a height where the second metal pattern is located, and
wherein a contact portion of the first protection film that is in contact with the third metal pattern is located outside of the first semiconductor layer in the plan view.

21. The semiconductor apparatus according to claim 20, wherein the contact portion is located outside of an edge of the first semiconductor layer in the plan view.

22. The semiconductor apparatus according to claim 21, wherein the third metal pattern is made of a material composed mainly of copper.

23. The semiconductor apparatus according to claim 16, wherein the first protection film extends to a surface of the first semiconductor layer that is opposite to the second semiconductor layer.

24. The semiconductor apparatus according to claim 16, wherein an insulating film is located between a side surface of the first semiconductor layer and the first protection film.

25. The semiconductor apparatus according to claim 16, wherein a shortest distance between the side surface of the first semiconductor layer and the first protection film is 300 nm or less.

26. The semiconductor apparatus according to claim 16, further comprising a support substrate,
wherein the first substrate and the second substrate are stacked on the support substrate.

27. A photoelectric conversion system comprising:
a semiconductor apparatus according to claim 1; and
a signal processing unit configured to generate an image using a signal output from the semiconductor apparatus.

28. A moving body comprising:
a semiconductor apparatus according to claim 1; and
a control unit configured to control movement of the moving body using a signal output from the semiconductor apparatus.

29. A semiconductor apparatus manufacturing method comprising:
preparing a bonded body obtained by stacking a first substrate including a first wiring structure and a first semiconductor layer and a second substrate including a second wiring structure and a second semiconductor layer;
forming a protection film on a top surface and a side surface of the bonded body, the protection film including a first protection film including nitrogen and a second protection film, the first protection film and the second protection film being located in this order; and
removing a part of the protection film to expose at least a part of the first protection film,
wherein, in the preparing the bonded body, a first metal pattern included in the first wiring structure and a second metal pattern included in the second wiring structure are bonded together to electrically connect the first semiconductor layer and the second semiconductor layer to each other, and in a planar view from a first semiconductor layer side, the second semiconductor layer is larger than the first semiconductor layer.

30. The semiconductor apparatus manufacturing method according to claim 29, further comprising bonding a support substrate after the removing the part of the protection film.

31. The semiconductor apparatus manufacturing method according to claim 29, wherein the first protection film includes silicon nitride or silicon oxynitride, and the second protection film includes silicon oxide.

32. The semiconductor apparatus manufacturing method according to claim 31, wherein in the removing a part of the protection film, a top surface of the protection film is planarized by a chemical-mechanical polishing method.

33. The semiconductor apparatus manufacturing method according to claim 29, wherein a thickness of the second protection film is ten times or more a thickness of the first protection film.

34. The semiconductor apparatus manufacturing method according to claim 29, wherein, prior to the forming the protection film, an insulating film is formed on a side surface of the first semiconductor layer.

35. The semiconductor apparatus manufacturing method according to claim 34,
wherein, in the preparing the bonded body, the first semiconductor layer includes a first region to which an impurity is added and a second region to which the impurity is not added,
wherein the insulating film is formed on a side wall of the first region, and
wherein in the removing the part of the protection film, a part of the first semiconductor layer is removed.

36. The semiconductor apparatus manufacturing method according to claim 29, wherein, in the removing the part of the protection film, a part of the first semiconductor layer is removed to set a height of the first semiconductor layer to be less than a height of the protection film.
